(19) United States
(12) Patent Application Publication
(10) Pub. No.: US 2013/0213456 A1
(43) Pub. Date: Aug. 22, 2013

(54) METHOD AND APPARATUS FOR MANUFACTURING A SOLAR MODULE AND A SOLAR MODULE HAVING FLEXIBLE THIN FILM SOLAR CELLS

(71) Applicants: Klaus Schlemper, Dresden (DE); Dieter Bergmann, Dresden (DE); Volker Brod, Bad Abbach/Lengfeld (DE)

(72) Inventors: Klaus Schlemper, Dresden (DE); Dieter Bergmann, Dresden (DE); Volker Brod, Bad Abbach/Lengfeld (DE)

(73) Assignee: Muhlbauer AG, Roding (DE)

(21) Appl. No.: 13/402,369

(22) Filed: Feb. 22, 2012

(51) Int. Cl. H01L 31/05; B32B 37/14; B32B 37/12; H01L 31/048; H01L 31/18

(52) U.S. Cl. 136/251; 438/66; 156/539; 257/E31.117

(57) ABSTRACT

A thin film solar module including a first film web, a series of electrically conductive contact pads arranged at intervals on the first film web, where the contact pads each have a first and a second area, and a series of flexible thin film solar cells. The thin film solar cells each include a first side which at least partially forms a first electrically conductive pole, a second side, which at least partially forms a second electrically conductive pole, a photovoltaically active layer composition, and at least one electrical contact located on the layer composition, which contacts the first electrically conductive pole, wherein the electrical conductor extends past a side of the photovoltaically active layered composition.

### BACKGROUND

A method and an apparatus for manufacturing a solar module with flexible solar cells, and in particular flexible thin film solar cells is described here, as well as a solar module which is manufactured with such an apparatus/according to such a method. The procedure described here, the corresponding apparatus for manufacturing a solar module, and the resulting product, namely the solar module, can also be realized with rigid solar cells (for example silicone solar cells) instead of the flexible thin film solar cells which are described here in detail.

Solar- or photovoltaic modules (including those of the type described here) transform incident sunlight directly into electrical energy. The most important component of a solar module is a plurality of solar cells. A solar module is characterized by its electrical connection values (in particular offload voltage and short circuit current). These depend on the characteristics of the individual solar cells and the quality of the connections between the solar cells within the module.

A solar module (including one of the type described here) usually has, in addition to the solar cells which are electrically connected with each other, an embedding material and a reverse-side construction. A cover layer provides protection from mechanical and weather influences. The reverse-side construction protects the solar cells and the embedding material from humidity and oxygen. It also provides mechanical protection for mounting of the solar modules, and electrical isolation. The reverse-side construction can be formed of glass or a compound film.

On the underside of a solar cell, a first electrode is located (normally the positive pole is on the underside of the solar cell), and on the upper side a second electrode is located (normally the negative pole is on the upper side of the solar cell). Normally, when solar cells are connected to a solar module, the underside of each cell is electrically connected to the upper side of a further cell.

### STATE OF THE ART

In particular, the following structures are, among others, are known; WO 2009148562A1—Solexant—relates to the connection of solar cells, in which a substrate is provided with a plurality of holes, a metallic electrode layer is applied to both sides of the substrate, to form an underside- and a back-electrode. A portion of the metal layer is scored about the circumference of one of or a plurality of the holes, in order to isolate the respective hole from the underside electrode. The underside- and the back-electrodes are scored lengthwise, to define neighboring cells. The neighboring cells are electrically connected with each other by a contact between the underside electrode of a cell and the back electrode of a further cell via at least one hole, which is positioned between the underside electrode scoring and the back electrode scoring. An absorptive layer and a transparent conductive layer are applied. The transparent conductive layer is scored lengthwise across a cell on one side of the row of connection vias, and a transparent conductive electrode is scored lengthwise across a cell on the opposite side of the same row of connection vias, wherein the scoring is positioned in immediate proximity to the row of connection vias and the scoring removes the transparent conductive layer (TCO).

It is known from US 2009 0025788 A1—Day4Energy—to use an electrode to contact multiple photovoltaic cells. A first group of vias embedded embedded in adhesive and a second group of vias perpendicular to the first group form a grid and are connected with respective contact rails.

DE 10 2009 060604 A1—Energetica Holding GmbH—relates to a solar module with a conductive plate and a method for manufacture. Solar cells connected in rows are connected with a copper strip or wire. In this way, the solar cell is contacted on the underside and connected with the neighboring cell on the upper side. The cells are laminated between two films.

US 2011 0197947 A1—Miasole—relates to solar cells, which are connected in series with wire connectors. The wire contacts a solar cell on its reverse side and a neighboring cell on the photovoltaic layer on the cell's front side.

DE 10 239 845 C1 describes an electrode for contacting an electrically conductive surface of a photovoltaic element, with an electrically isolating, optically transparent film, with an adhesive layer applied to a surface of the film, and with a first group of parallel, electrically conductive wires, which are embedded in the adhesive layer, which protrude from the adhesive layer with a portion of their surface, and, on the surface which protrudes from the adhesive layer, are covered with a layer of an alloy with a low melting point. The wires are electrically connected to the first group with a first contact strip.

DE 10 2008 046 327 A1 relates to an arrangement of a plurality of production devices as an installation for processing solar cells into a module. The installation comprises production devices for the following steps: providing the support, pre-confectioning of solar cells by applying contact wires, arrangement of perpendicular contact wires on the support, placement of the pre-confectioned solar cells on the support, connecting the pre-confectioned solar cells lengthwise to the contact wires, connecting the pre-confectioned solar cells crosswise to the perpendicular contact wire and, to complete the module, joining the solar cells which are on the support to a support glass.

WO 94/22 172 relates to the use of a roll laminator in place of previously used vacuum plate laminators. The plastic films used are not particularly well suited for encapsulation of solar modules. The films are neither impact resistant enough nor suitably weather resistant, nor is the adhesive layer soft enough to effectively mechanically protect the easily breakable solar cells.

US 2010 0043863 A1—Miasole—and US 2001 0308467 A1—Amerasia Internat. Technology—show further technological background.

There are several different disadvantages of the connection types and connection manufacturing means of the previously described forms. The requirement exists for thin film solar modules that they be bendable for mounting, and also during normal operation. The wires for serially connecting the solar cells are, however, less flexible than the very thin and sensitive photovoltaic layers of the solar cells. Therefore, mechanical stress can build up between the ends of the wires and the photovoltaic layers during placement or due to different thermal expansion coefficients of the wire material relative to the material of the solar cells. These mechanical stresses can cause the ends of the wires to disconnect from the solar cells or cause the ends of the wires to damage the surface of the solar cells. Furthermore, manufacture of the previously described connection types and connection manufacturing means is not particularly efficient.

Several of the mounting techniques produce large thermal stresses when connecting the solar cells. Due to the temperature differences which arise between the hot soldering points and the cooler surroundings, the solar cells can be prone to formation of fissures. For other modules, it can happen that the strip conductors or the metal paste which forms the emitter does not provide a stable cohesion. The wind- and snow-loads which act on a solar module in a daily or seasonal cycle can then break the emitter. This separates many of the solar cells from the electrical connection of the solar module, and reduces its output power. In thin film modules, the internal electrical cell connections can develop slight defects; for example, the cells can be connected with copper ribbons, which are affixed with an insufficiently hardened conductive adhesive. In this case, the line resistance of the solar module is increased considerably, and its output power sinks.

### PROBLEM TO BE SOLVED

The problem is therefore to provide a cost effective, fast method and a corresponding apparatus for connecting solar cells within a solar module, in order to facilitate a cost effective production of solar energy, in that the manufacturing costs are lower with respect to previous solutions and the durability of the entire solar module is improved with respect to previous solutions.

### SUGGESTED SOLUTIONS

A method for manufacturing a solar module with flexible solar cells, particularly with flexible thin-film solar cells, can have the following steps:

providing a first film web for applying flexible thin film solar cells;

applying a series of spaced electrically conductive contact pads to the first film web providing a series of flexible thin film solar cells, which have

a first side, which is at least partially formed as a first electrically conductive pole and a second side, which is at least partially formed as a second electrically conductive pole,

a photovoltaically active layered structure,

and

at least one electrical conductor located on the layered structure, and contacting the first pole, wherein

the electrical conductor extends past a side of the photovoltaically active layered structure;

applying a thin film solar cell of the series to the first film web, in such a way that the second electrically conductive pole contacts a first area of a first one of the contact pads on the first film web, and

the electrical conductor which contacts the first electrically conductive pole contacts a second area of a second contact pad adjacent to the first contact pad on the first film web with a portion which extends past the side of the photovoltaically active layered structure.

This approach enables a very efficient manufacture of solar modules, as the thin film solar cells can be applied directly to the first (reverse-side-) film web in a single operation of a continuous process. By separating the serial connections of two thin-film solar cells into two segments, namely the contact pad and the electrical conductor, or the contact pad and the second pole, respectively, the respective material pairing and its respective connection technique is optimizable.

In the state of the art, a front contact, usually of conductive silver paste as conductive material, is printed as an electric conductor on the upper side of the solar cell for collecting the electricity produced.

Through the separation of the serial connection of two solar cells into two segments proposed here, the materials which are used can be optimally tailored to the solar cell materials. Here, in one alternative, the contact pad with its two areas can be formed of one or two materials with a different electric conductivity, which border each other and are in electrical contact with each other.

If, for example, the second (underside) electrically conductive pole of the solar cell is composed of stainless steel film or aluminum film, the contact pad can be formed with a corresponding contact adhesive to be low resistive and mechanically stable. The front contact of the neighboring cell is then connected using electrical conductors such as, for example, a number of copper or aluminum conductors. The electrical conductor can be a wire with or without an insulating sheath, an electrical strip line with our without an insulating sheath, an electrically conductive mesh, an elongated conductor, a loop-, meandering-, spiral- or zigzag-form of an electrical conductor.

In place of the film/of the flexible cover layer, an e.g. thermoplastic adhesive mass can be applied at intervals to the electric conductor to partially envelop the electrical conductor, before/as this is dispensed onto the photovoltaically active layer composition.

The connection between the contact pads and the electrical conductors can be implemented by contact adhesive or also by laser welding, soldering, or other connection technologies. The contacting of the first electrically conductive pole on the upper side of the solar cell to the electrical conductor is preferably effected with a (roll-) lamination process. In this lamination process, the electrical conductors are pressed, together with the provided encapsulation material/the thermoplastic (cover-) film made from EVA (ethylenevinylacetate), TPU (thermoplastic polyurethane), etc. onto the surface of the cell (e.g. TCO, i.e. transparent, electrically conductive oxide “transparent conducting oxides”-layer), and laminated, where appropriate under negative pressure, with application of pressure and heat, or (pre-) fixed for a later lamination.

In preparation for this contact/lamination step, the electrical conductors can have been fixed in a preprocessing step through the effects of pressure and temperature for a particular time period—preferably in a roll-to-roll process—onto the encapsulation material. (Here, a partial sinking or embedding of the electrical conductor in the encapsulation material/the thermoplastic (cover-) film of EVA, TPU, etc. can be performed.

Before providing the series of flexible thin film solar cells, a flexible cover layer, which partially envelops the electrical conductor, can be applied to the first side of the layer composition and to the electrical conductor of each of the flexible thin film solar cells.

A preferred alternative of this can be to heat the electrical conductor before applying it to the photovoltaically active layer composition, and then to partially embed or sink the electrical layer into the flexible cover layer. Alternatively or in addition, the flexible cover layer, for example a thermoplastic film web or a film approximately corresponding to the form of the extended electrical conductor with a corresponding projecting boundary, can be heated and thereby softened, in order to partially embed sink the electrical conductor into the flexible cover layer.

This intermediate product of electrical conductor and flexible cover layer can be provided as “infinite tape” on a roll or as portioned areas or strips, to be applied to each of the series of flexible thin film solar cells. The infinite tape from the roll can also be apportioned before or after application to the series of flexible thin film solar cells, respectively.

“Partially enveloped” is to be understood here as the electrical conductor is only partially embedded or sunk into the flexible cover layer with respect to the cross section and/or with respect to longitudinal extension of the electrical conductor.

The process described here is also implementable with rigid solar cells.

The first film web can preferably be a weather resistant flexible film, which is coated with a self-adhesive layer. Alternatively, the first film web can be a weather resistant flexible film, which is coated with a thermoplastic layer. Then, the connection between the first film web and the flexible thin film solar cells can be achieved by heat application.

For assembling the flexible thin film solar cells on the first film web, a plurality of flexible thin film solar cells can be arranged length- and/or crosswise relative to the transport direction of the first film web. In this way, the desired configuration of serial and/or parallel connections of the individual flexible thin film solar cells to one of the cell fields building the solar module can be very flexibly determined.

The electrically conductive contact strips can be applied to the flexible thin film solar cells parallel to the transport direction of the first film web by multiple neighboring dispensers which contain rolls of electrically conductive paste and are generally arranged parallel to the transport direction of the first film web. Alternatively or additionally, the electrically conductive contact strips can be applied to the flexible thin film solar cells perpendicularly to the transport direction of the first film web by at least one dispenser which is arranged generally perpendicular to the transport direction of the first film web and contains a roll of conductive contact strips or by a dispenser with electrically conductive paste. As such, it is possible to electrically connect the thin film solar cells with each other in series and/or in parallel, very flexibly and efficiently.

The individual flexible thin film solar cells can also be provided in a container as separate parts. Analogously, the flexible thin film solar cells can be provided in a stacking area.

The stacking area can have a—removable—container, in which the flexible thin film solar cells are provided.

The second film web can be laminated to the first film web and the flexible thin film solar cells with a roll laminator. The roll laminator has at least two opposing cylinders which rotate at a defined speed and press a composite of the first web and the flexible thin film solar cells together with a defined pressure at a defined temperature. This allows solar modules of high quality to be produced.

The contact between the electrical conductor and the second area of the second contact pad can be provided through pressing.

The pressing can be performed by introducing heat in a temperature range of approximately 120° C. to approximately 170° C. for a period of less than 20 seconds and, where appropriate, with negative pressure for at least a portion of the period.

The first film web can be transported in a transport direction, and can be adapted to apply a plurality of series of spaced electric conducting contact pads next to each other at lateral intervals, and to apply flexible thin film solar cells preferably simultaneously to the first film web and to the series of spaced electrically conducted contact pads.

A transparent, flexible, thermoplastic second film web can be laminated to the first film web and to the flexible thin film solar cells.

A solar module strand formed of the first and second film webs and the flexible thin film solar cells located between them can be wound up on a roll.

Each of the electrically conductive contact pads can comprise a conductive strip material with or without an adhesive layer facing the first film web, or conductive paste or a metal strip material (such as copper- or aluminum-containing film) with or without an adhesive layer facing the first film web.

The electrical conductor can be formed of a conductive strip material, of metal strip material, of wire material or of conductive paste.

The first side of each flexible thin film solar cell can at least partially comprise a metal layer, and this metal layer can form a first electrically conductive pole, which is positive pole, and/or in which the opposite second side of the flexible thin film solar cell, which faces away from the film, can at least partially form a second electrically conductive pole, which is a negative pole.

The second film web can be laminated in a temperature range of approximately 120° C. to approximately 170° C. for a period of less than 10 minutes and, where appropriate, with negative pressure for a portion of the period.

For the first and/or the second film web, a thermoplastic polyurethane film or another weather resistant (reverse side-) film can be used.

The pressing can be achieved with a roll press, which has at least a cylinder and a counter surface or two opposing cylinders, which rotate at a defined speed and press a composite of the first web and the flexible thin film solar cells together with a defined pressure at a defined temperature.

Accordingly, an apparatus for manufacturing a solar module can have the following modules or components: a device for providing a first film web; a device for applying a series of spaced electrically conductive contact pads to the first film web; a device for providing a series of flexible thin film solar cells, each of which has a first side, which is at least partially formed as a first electrically conductive pole and a second side, which is at least partially formed as a second electrically conductive pole, a photovoltaically active layered structure, and at least one electrical conductor located on the layered structure and contacting the first pole, wherein the electrical conductor extends past a side of the photovoltaically active layered structure; a device for applying a thin film solar cell of the series to the first film web, in such a way that the second electrically conductive pole contacts a first area of a first one of the contact pads on the first film web, and the electrical conductor which contacts the first electrically conductive pole contacts a second area of a second contact pad adjacent to the first contact pad on the first film web with a portion which extends past the side of the photovoltaically active layered structure.

A pressing device can be provided to establish/improve the contact between the electrical conductor and the second area of the second contact pads.

The pressing device can also comprise a heating device, to introduce a temperature in a range of approximately 120° C. to approximately 170° C. for a period of less than 20 seconds and, where appropriate, with negative pressure for at least for a portion of the period to the contact between the second electrically conductive pole and the first contact pad on the first film web, and/or to the contact between the electrical contact which contacts the first electrically conductive pole and the second contact pad on the first film web.

A transport device can transport the first film web in a transport direction and multiple devices can be provided to each apply a series of spaced electrically conductive contact pads next to each other with lateral spacing, and multiple devices to each apply a series of flexible thin film solar cells to the first film web and to the series of spaced electrically conductive contact pads.

A feeding device and a laminating device can be provided for laminating a transparent, flexible thermoplastic second film web onto the first film web and onto the flexible thin film solar cells.

A spool device can be provided for a solar module strand formed from the first and the second film webs and the flexible thin film solar cells located between them.

The feeding device for each of the electrically conductive contact pads can be adapted to feed a conductive strip material with or without an adhesive layer facing the first film web or a metal strip material with or without an adhesive layer facing the first film web, or conductive paste onto each of the electrically conductive contact pads.

The feeding device for the electrical conductors can be adapted to feed a conductive strip material, a metal strip material, a wire material, a mesh material, or a conductive paste, with our without a flexible cover layer, respectively, onto the electrical conductors.

Multiple neighboring dispensers can be provided arranged generally in parallel to the transport direction of the first film web and/or arranged generally perpendicular to the transport direction, the dispensers having rolls of electric conductors or dispensers with electrically conductive paste in order to apply electrical conductors to the flexible thin-film solar cells in parallel to or perpendicular to the transport direction of the first film web, in order to connect the flexible thin film solar cells with each other in serial and/or in parallel.

A roll press can be provided, which has at least two opposing cylinders, which rotate with a defined speed and press a composite of the first web and the flexible thin film solar cells together with a defined pressure at a defined temperature.

Where a guided electrical conductor was previously mentioned, this can be a wire, an electrical strip conductor, an electrically conductive mesh, an extended conductor, a loop-, meandering-, spiral-, or zigzag-form of an electrical conductor. This electrical conductor can furthermore be applied together with the flexible cover layer as the intermediate product described above from the dispenser to the electrically conductive contact pads and to the flexible thin film solar cells.

The cover layer AS can be distributed on the solar cells as individual pieces, which have approximately the size of a solar cell and extend over the corresponding solar cell toward the respective contact pad.

To ensure that the lamination by means of suitable application of pressure, temperature, and possible vacuum pressure with a corresponding progression for a predefined time works, and the individual solar cells are all fully insulated from the environment, preferably a further film F2 (EVA, thermoplastic film, TPU, etc.) is applied to the surface of the cell network (solar module) by roll lamination.

Before the final transparent film web F2 is laminated, a further film (EVA, TPU) may in certain circumstances be necessary, to smooth out possible unevenness.

In the above, the electric conductor can be applied together with the cover layer to the thin film solar cells, or the electrical conductor is applied before the flexible cover layer. It is also possible to forego the flexible cover.

A thin film solar module can also be provided with the following features: a first film web; a series of electrically conductive contact pads arranged at intervals on the first film web, the film pads each having a first and a second area; a series of flexible thin film solar cells, of which each has a first side which at least partially forms a first electrically conductive pole and has a second side, which at least partially forms a second electrically conductive pole, has a photovoltaically active layer composition, and has at least one electrical contact located on the layer composition, which contacts the first electrically conductive pole, wherein the electrical conductor extends past a side of the photovoltaically active layered composition wherein the thin film solar cells are arranged on the first film web in such a way that the second electrically conductive pole contacts a first area of a first one of the contact pads on the first film web, and the electrical conductor which contacts the first electrically conductive pole contacts a second area of a second contact pad adjacent to the first contact pad on the first film web with a portion which extends past the side of the photovoltaically active layered structure.

### SHORT DESCRIPTION OF THE DRAWINGS

Further goals, features, advantages, and applications are apparent from the following description of embodiments, which are not to be interpreted as limiting, with reference to the respective drawings. All of the features described and/or visually illustrated form the disclosed subject matter, alone or in any combination, and independently from their grouping in the claims or their dependencies. The dimensions and proportions of the components shown in the figures are not necessarily drawn to scale; they can differ from those illustrated in the embodiments to be implemented.

FIG. 1 shows a flexible thin film solar cell for use in the way described here, in a schematic cross section.

In FIG. 2, a process flow is illustrated to manufacture thin film solar modules in the way described herein.

FIG. 3 shows the contact of two thin film solar cells from FIG. 1 connected in series, magnified in schematic cross section.

In FIG. 4, a roll laminator is shown in schematic cross section for use in the way described herein.

### DETAILED DESCRIPTION OF THE EMBODIMENTS

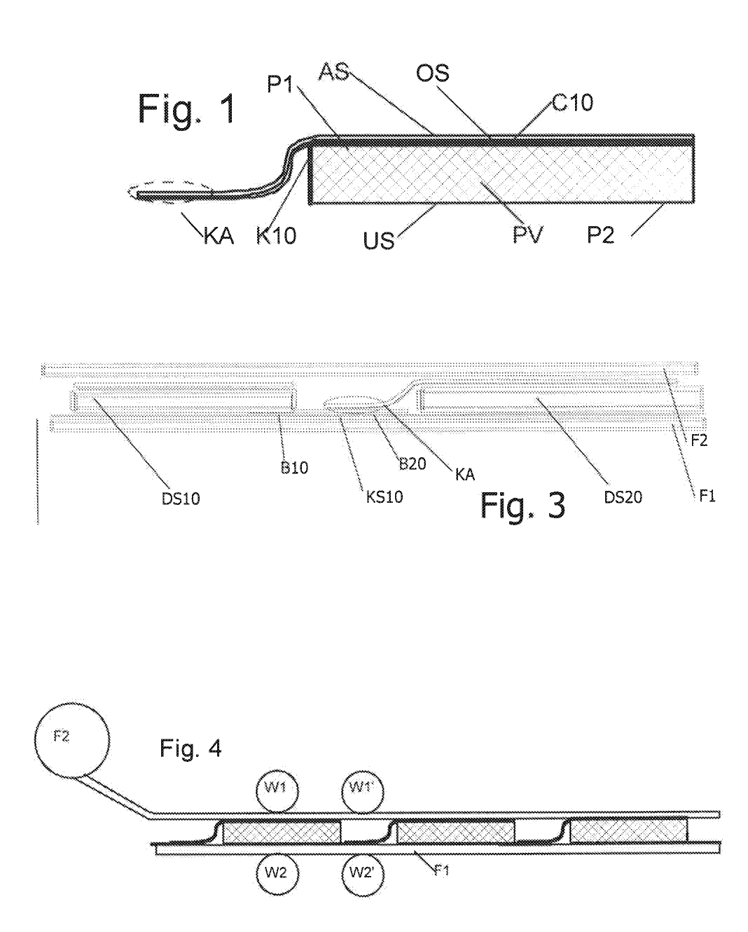

As shown in detail in FIG. 1, a flexible thin film solar cell of this type has the following construction: a first side OS (the upper side) of the absorptive material AM at least partially forms a first electrically conductive pole P1. A second side US (the underside) of the absorptive material AM forms a second electrically conductive pole P2. The absorptive material AM comprises a photovoltaically active layer construction PV. The absorptive material AM has a flexible cover layer AS located on the first side OS of the layer composition PV and at least one electrical conductor C10, C20 . . . , which is located between the layer composition PV and the cover layer AS, and contacts the first electrically conductive pole P1. The cover layer AS and the electrical conductor C10, C20 . . . can be an intermediate product, in which the electrical conductor C10, C20 . . . is partially fixed on/to the cover layer AS with respect to its cross section, but it is at least partially exposed and electrically conductive along its length to an extent, that the photovoltaically active layer composition PV, more precisely. The first side OS (e.g. the TCO-layer) of the absorptive material AM contacts electrically conductively. The electric conductor C10, C20 . . . can be partially embedded in the cover layer AS. In this version the flexible cover layer AS and the electric conductor C10, C20 . . . extend sideways over the photovoltaically active layer composition PV.

In the exemplified version, the flexible cover layer AS and the electrical conductor C10, C20 . . . extend sideways over the photovoltaically active layer composition PV sideways along an edge of the layer composition PV to such an extent that the flexible cover layer AS and the electrical conductor C10, C20 . . . beside the layer composition PV approximately reach the level of the second side US (the underside) of the absorptive material AM. There, the flexible cover layer AS and the electrical conductor C10, C20 . . . form a horizontally oriented contact area KA (which is approximately in alignment with the second side US of the absorber material AM). Other versions are also possible, in which the electrical conductor is processed without the flexible cover layer AS. In this case, only the electric conductor C10, C20 . . . extends past the side of the photovoltaically active layer composition PV in the way described above. To prevent damage (short circuit) of the layer composition PV by the electric conductors C10, C20 . . . a protective or isolative coating K10 can be arranged on the side surfaces of the layer composition PV, past which the flexible cover layer AS and the electrical conductor C10, C20 . . . extend.

This protective or isolative coating K10 can, in a preferred embodiment, also be bent upward toward the first side OS of the absorber material AM. Further, this protective or isolative coating K10 can extend up to the boundary area adjoining the side surfaces of the layered structure PV (for example approximately 5% to 20% of the total area) of the first side OS of the absorber material AM. This serves to effectively prevent damage to the layered structure PV by the electrical conductor C10, C20 . . . along the boundary of the absorber material AM.

The electrical contacts C10, C20 . . . for each thin film solar cell can be conductive strips or wires arranged parallel to each other, which extend past an edge of the layered composition PV. The electrical conductors C10, C20 . . . can, however, also be spiral-form or meander-form and the like placed conductor strips, mesh structures or wires, of which one end extends past an edge of the layered composition PV.

In the manufacturing process of the solar modules, the solar cells are connected step-by-step as follows, for example (see also FIG. 2). After placing two neighboring solar cells on the first film web F1, the back contact of one of the two solar cells is connected to the prepared contact pad KS10 through direct contact and/or by means of suitable contact material, for example a contact adhesive. Before the electrical conductor C10, C20 . . . is applied to contact the first pole P1 on the upper side OS of the cell, in one embodiment, the front side of the cell as well as the upper edge oriented toward the contact pad KS10 between the upper side OS of the cell and the contact pad KS10 can be isolated with a suitable material (polyimide film strip, e.g. KAPTON® or other isolation strip, isolation adhesive).

The encapsulation material AS prepared together with the electrical conductor C10, C20 . . . is applied to the upper side OS of the solar cell and trimmed such that the electrical conductors C10, C20 . . . extend past the upper solar cell surface and are arranged over the contact pad KS10. The electrical conductors C10, C20 . . . are arranged on the encapsulation material, on the side facing toward the cell surface. The electrical connection and fixing of the electrically conductive material with the contact pad K10 is effected by the electrical connecting process by means of laser, welding, soldering or other suitable connecting technologies. The resulting, initially one-sided connection of the electrical contact can be finished by an ensuing roll lamination process, in which pressure and temperature can—depending on the material—act on the assembly for a defined time period. Here, the electrical contact is pressed and fixed along the entire surface (front side surface (e.g. TCO-layer)) of the solar cell for contacting. This is effected by means of the encapsulation material, which temporarily liquidizes during the lamination process step (pressure, time, temperature and, where appropriate, vacuum pressure) and subsequently ensures fixation as a transparent adhesive layer.

The method described here can, in principle, also be applied to rigid solar cells (e.g. silicone solar cells).

A significant advantage which results from the split connection contact composition is (i) the applied material pairings of the electrical conductor material (e.g. copper, aluminum) and the contact pad are adaptable to each other, (ii) the optimal connection technology (laser, welding, soldering, contact adhesive etc.), as well as (iii) the ability to select the lower- or backside material of the solar cells (e.g. steel film, stainless steel film, aluminum etc.) on the electrical connection to the following cell. Because of this, the best suited materials can be selected for the qualitative, technical certification of the solar module as well as for cost optimized manufacturing. The roll-to-roll manufacturing concept is optimally suited for this method and simultaneously satisfies the requirements for optimal productivity.

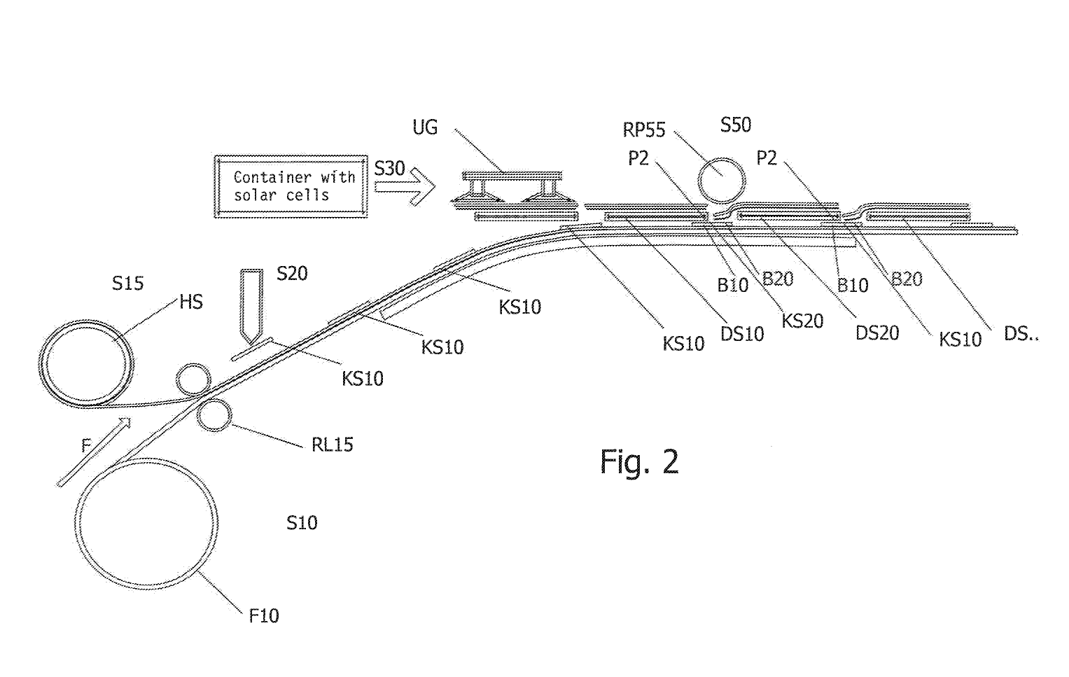

FIG. 3 shows flexible thin film solar cells, as they are used here. The second side (here, the side facing away from the light source which provides energy during operation, in other words the underside) of each of the flexible thin film solar cells has, at least partially, an electrically conductive layer. This conductive layer forms an electrically conductive positive pole (anode). The first side of the flexible thin film solar cell (here, the side facing the light source which provides energy during operation, in other words the upper side) forms the electrically conductive negative pole (cathode).

In FIG. 2, the procedure for manufacturing thin film solar modules is illustrated. In a first step S10, a first flexible film web F10 is provided from a roll. In an optional step S15, an adhesive or adherent layer HS is laminated to the film web F10 by means of a roll laminator RL15 from a roll. The arrangement of first film web F1 and adhesive or adherent layer HS is put through the roll laminator RL15 is step S15. In a further step S20, a series of spaced electrically conductive contact pads KS10 are applied to the first film web F10 on the film web F10 (or, if present, to the adhesive or adherent layer HS) in a transport direction F of the film F1. These electrically conductive contact pads KS10 can be formed of a conductive strip material with or without an adhesive layer facing the first film web F10, a metal strip material with or without an adhesive layer facing the first film web F10, or of conductive paste. In a further step S30, a series of flexible thin film solar cells DSZ1, DSZ20 of the type described above, see FIGS. 1, 2) are applied to the first film web F10 (or, if present, to the adhesive or adherent layer HS) with a magnet or vacuum gripper UG.

The application of one of the thin film solar cells DSZ10, DSZ20 . . . of the series to the first film web F10 takes place in such a way that the second electrically conductive pole P2 contacts a first one of the contact pads KS10 on the first film web F1 in a first area B10, and the electrical conductor C10, C20 . . . which contacts the first electrically conductive pole P1, contacts a second contact pad KS20 adjacent to the first contact pad KS10 on the first film web F1 in a second area B20. The respective first and second areas B10, B20 of a contact pad are adjacent to each other.

In a further step S50, the contact between the electrical conductor and the second area B20 of the second contact pad KS20 is established by pressing, for example by means of a roll press RP55. In this step S50, the contact between the second electrically conductive pole P2 and the first contact pad KS20 on the first web F1 in the first area B10 can be established or intensified through pressing, for example by means of the roll press RP55. To this end, the assembly of the first film web F1, flexible thin solar cells DSZ10, DSZ20 . . . are fed through the roll press PR55 in step S50.

Alternatively or in addition to establishing/improving the contact between the electrical conductor and the second area of the second contact pad by pressing, this can also be achieved by lasering, welding, soldering, or other contacts technologies.

The first film web F10 can be transported in a transport direction F. At lateral intervals, multiple series of spaced electrically conductive contact pads KS10 are applied next to each other. Next, multiple series of flexible thin film solar cells DSZ10, DSZ20 are applied to the first film web F10 in the way described above, at lateral intervals next to each other.

To this end, multiple neighboring dispensers are provided generally lengthwise and/or crosswise to the transport direction of the first film web. These dispensers have rolls of electrical conductors or provide electrically conductive paste to the flexible thin film solar cells, to connect the flexible thin film solar cells to each other electrically in serial and/or in parallel.

In a lamination step, a lamination of a second film web F2 onto the first film web F1 and the flexible thin film solar cells takes place. The second film web F2 is thermoplastic, transparent, flexible and very durable with respect to ultraviolet light.

The result of the pressing in step S50 and the lamination is illustrated in cross-section in FIG. 4 in a magnified view.

The second film web F2 is laminated onto the first film web F10 and the flexible thin film solar cells with a roll laminator RL. The roll laminator RL has at least a roll pair of two opposing cylinders W1, W2, between which the stack of the first film web F1 with the flexible thin solar cells and the second film web F2 is fed. The opposing cylinders W1, W2 rotate with a defined speed, and press a combination of the second film web, the first film web and the flexible thin film solar cells onto each other with a defined pressure at a defined temperature. In this way, the individual components of the composite are connected in a firmly bonded, close, and as bubble-free way as possible.

This is for example illustrated in FIG. 4. The roll laminator RL illustrated here exemplarily has one or more roll pairs formed of cylinders W1, W2; W1′, W2′ to laminate a self-adhesive cover film DF onto the film web F1. Alternatively, a film without an adhesive layer can be put through an adhesive application station and then laminated onto the film web F1 and the flexible thin film solar cells. Such a roll laminator can also be used in the previous steps as RL15 or as RP55.

The pressing of the contacts or of the second film web F2, respectively, can be performed under application of a temperature in a range of approximately 120° C. to approximately 170° C. for a period less than 20 seconds and, if appropriate, with underpressure for at least a part of the time period.

The solar modules created thus are then examined and finally separated or rolled up into reel packaging.

The product, apparatus and method details given above are described in combination. It is, however, noted that they are each independent from each other and freely combinable with each other. The proportions of the individual parts and sections shown in the figures to each other and their dimensions and relative proportions are not be understood as limiting. Rather, the individual dimensions and relative proportions can also diverge from those shown.

1. A method for manufacturing thin film solar modules, said method comprising:
providing a first film web for applying flexible thin film solar cells;
applying a series of spaced electrically conductive contact pads to the first film web;
providing a series of flexible thin film solar cells, which have:
a first side, which is at least partially formed as a first electrically conductive pole, and
a second side, which is at least partially formed as a second electrically conductive pole,
a photovoltaically active layered structure,
and
at least one electrical conductor located on the layered structure, and contacting the first pole, wherein
the electrical conductor extends past a side of the photovoltaically active layered structure;
applying a thin film solar cell of the series to the first film web, in such a way that
the second electrically conductive pole contacts a first area of a first one of the contact pads (KS10) on the first film web, and
the electrical conductor which contacts the first electrically conductive pole contacts a second area of a second contact pad adjacent to the first contact pad on the first film web with a portion which extends past the side of the photovoltaically active layered structure.

2. The method for manufacturing thin film solar modules according to claim 1, wherein a flexible cover layer which partially surrounds the electrical conductor is applied to the first side of the layered structure and the electrical conductor of each of the flexible thin film solar cells.

3. The method for manufacturing thin film solar modules according to claim 1, wherein in a further step, the contact between the electrical conductor and the second area and the second contact pad is produced by pressing, (laser)-welding, soldering or pasting.

4. The method for manufacturing thin film solar modules according to claim 1, wherein the step of pressing is performed by introducing heat in a temperature range of approximately 120° C. to approximately 170° C. for a period of less than 20 seconds and, where appropriate, with negative pressure for at least a portion of the period.

5. The method for manufacturing thin film solar modules according to claim 1, in which the first film web is transported in a transport direction, and applying multiple series of:
spaced electrically conductive contact pads, and
flexible thin film solar cells simultaneously to the first film web and to the series of spaced electrically conductive contact pads,
at lateral intervals side-by-side.

6. The method for manufacturing thin film solar modules according to claim 1, wherein in a further step a transparent, flexible, thermoplastic second film web is laminated onto the first film web and the flexible thin film solar cells.

7. The method for manufacturing thin film solar modules according to claim 1, wherein in a further step a solar module strand composed of the first and the second film webs and the flexible thin film solar cells located between them is wrapped up.

8. The method for manufacturing thin film solar modules according to claim 1, wherein each of the electrically conductive contact pads comprises a conductive strip material with or without an adhesive layer facing the first film web, or a metal strip material with or without an adhesive layer facing the first film web, or conductive paste.

9. The method for manufacturing thin film solar modules according to claim 1, wherein the electrical conductor comprises a conductive strip material made of metal strip material, grid material, wire material, or conductive paste, with or without a flexible cover layer, respectively.

10. The method for manufacturing thin film solar modules according to claim 1, wherein the first side of each flexible thin film solar cell is at least partially covered with a metal layer, and this metal layer forms the first electrically conductive pole, which is a positive pole, and/or in which the opposite second side of the flexible thin film solar cell, which faces away from the film, at least partially forms the second electrically conductive pole, which is a negative pole.

11. The method for manufacturing thin film solar modules according to claim 4, in which the second film web is laminated with heat in a temperature range of approximately 120° C. to approximately 170° C. for a period of less than 10 minutes and, where appropriate, with negative pressure for a portion of the period.

12. The method for manufacturing thin film solar modules according to claim 1, wherein a thermoplastic polyurethane film is used for the first and/or second film web.

13. The method for manufacturing thin film solar modules according to claim 1, in which the individual flexible thin film solar cells are provided in a container, and/or the solar module strand formed of the first and second film webs and the flexible thin film solar cells are located between them, after separating the solar modules from the solar module strand, the solar modules are deposited in a stack area.

14. The method for manufacturing thin film solar modules according to claim 1, in which the electrical conductor is applied to the flexible thin film solar cells parallel to the transport direction of the first film web by multiple neighboring dispensers which contain rolls of electrically conductive paste and are generally arranged parallel to the transport direction of the first film web, and/or in which the electrically conductive contact strips are applied to the flexible thin film solar cells perpendicularly to the transport direction of the first film web by at least one dispenser which is arranged generally perpendicular to the transport direction of the first film web and contains a roll of conductive contact strips or by a dispenser with electrically conductive paste, in order to electrically connect the flexible thin film solar cells in series and/or in parallel.

15. The method for manufacturing thin film solar modules according to claim 1, in which the step of pressing is performed with a roll press, which has at least two opposing cylinders, which rotate at a defined speed and press a composite of the first web and the flexible thin film solar cells together with a defined pressure at a defined temperature.

16. An apparatus for manufacturing thin film solar modules, said apparatus comprising:
a device for providing a first film web;
a device for applying a series of spaced electrically conductive contact pads to the first film web;
a device for providing a series of flexible thin film solar cells, each of which has
a first side, which is at least partially formed as a first electrically conductive pole, and
a second side, which is at least partially formed as a second electrically conductive pole,
a photovoltaically active layered structure,
and
at least one electrical conductor located on the layered structure and contacting the first pole, wherein
the electrical conductor extends past a side of the photovoltaically active layered structure; and
a device for applying a thin film solar cell of the series to the first film web, in such a way that:
the second electrically conductive pole contacts a first area of a first one of the contact pads on the first film web, and
the electrical conductor which contacts the first electrically conductive pole contacts a second area of a second contact pad adjacent to the first contact pad on the first film web with a portion which extends past the side of the photovoltaically active layered structure.

17. The apparatus for manufacturing thin film solar modules according to claim 16, wherein a flexible cover layer which partially surrounds the electrical conductor is arranged on the first side of the layered structure and the electrical conductor of each of the flexible thin film solar cells.

18. The apparatus for manufacturing thin film solar modules according to claim 16, with a pressing device to create a contact between the electrical conductor and the second area and the second contact pad.

19. The apparatus for manufacturing thin film solar modules according to claim 16, wherein the pressing device also comprises a heating device, to introduce a temperature in a range of approximately 120° C. to approximately 170° C. for a period of less than 20 seconds and, where appropriate, with negative pressure for at least for a portion of the period to the contact between the second electrically conductive pole and the first contact pad on the first film web, and/or to the contact between the electrical contact and the second contact pad on the first film web.

20. The apparatus for manufacturing thin film solar modules according to claim 16, with a transport device to transport the first film web in a transport direction, and multiple devices to each apply a series of spaced electrically conductive contact pads next to each other with lateral spacing, and multiple devices to each apply a series of flexible thin film solar cells to the first film web and to the series of spaced electrically conductive contact pads.

21. The apparatus for manufacturing thin film solar modules according to claim 16, with a feeding device and a laminating device for laminating a transparent, flexible thermoplastic second film web onto the first film web and to the flexible thin film solar cells.

22. The apparatus for manufacturing thin film solar modules according to claim 16 with a spool device for a solar module strand formed from the first and the second film webs and the flexible thin film solar cells located between them.

23. The apparatus for manufacturing thin film solar modules according to claim 16, wherein the feeding device feeds a conductive strip material with or without an adhesive layer facing the first film web or a metal strip material with or without an adhesive layer facing the first film web, or conductive paste onto each of the electrically conductive contact pads.

24. The apparatus for manufacturing thin film solar modules according to claim 16, wherein the feeding device feeds a conductive strip material, a metal strip material, a wire material, a mesh material, or a conductive paste, with or without a flexible cover layer, respectively, onto the electrical conductors.

25. The apparatus for manufacturing thin film solar modules according to claim 16, in which the individual flexible thin film solar cells are lifted from a container and placed on the first film web by a placement device, and/or the finished solar module strand is separated into single solar modules by a separating device, which are placed in a stacking region by a stacking device.

26. The apparatus for manufacturing thin film solar modules according to claim 16, with multiple neighboring dispensers arranged generally parallel to the transport direction of the first film web, the dispensers having rolls of electric conductors or dispensers with electrically conductive paste are applied to the flexible thin film solar cells parallel to the transport direction of the first film web, and/or dispensers arranged generally perpendicular to the transport direction of the first film web with a roll of conductive contact strips or a dispenser with electrically conductive paste are applied to the flexible thin film solar cells perpendicular to the transport direction of the first film web, in order to connect the flexible thin film solar cells with each other in serial and/or in parallel.

27. The apparatus for manufacturing thin film solar modules according to claim 16, with a roll press, which has at least two opposing cylinders, which rotate at a defined speed and press a composite of the first web and the flexible thin film solar cells together with a defined pressure at a defined temperature.

28. A thin film solar module comprising:
a first film web;
a series of electrically conductive contact pads arranged at intervals on the first film web, the contact pads each having a first and a second area;
a series of flexible thin film solar cells, of which each
has a first side which at least partially forms a first electrically conductive pole, and
has a second side, which at least partially forms a second electrically conductive pole,
has a photovoltaically active layer composition, and
has at least one electrical contact located on the layer composition, which contacts the first electrically conductive pole, wherein
the electrical conductor extends past a side of the photovoltaically active layered composition wherein
the thin film solar cells are arranged on the first film web in such a way that:
the second electrically conductive pole contacts a first area of a first one of the contact pads on the first film web, and
the electrical conductor which contacts the first electrically conductive pole contacts a second area of a second contact pad adjacent to the first contact pad on the first film web with a portion which extends past the side of the photovoltaically active layered structure.

29. The thin film solar module according to claim 28, wherein a flexible cover layer partially surrounds the electrical conductor on the first side of the layer composition and the electrical conductor of each of the flexible thin film solar cells.
